(19) United States
(12) Patent Application Publication
(10) Pub. No.: US 2019/0385843 A1
(43) Pub. Date: Dec. 19, 2019

(54) METHOD OF FORMING METAL FILM AND FILM FORMING APPARATUS

(71) Applicant: TOKYO ELECTRON LIMITED, Tokyo (JP)

(72) Inventors: Satoshi WAKABAYASHI, Nirasaki City (JP); Motoko NAKAGOMI, Nirasaki City (JP); Hideaki YAMASAKI, Nirasaki City (JP)

(21) Appl. No.: 16/441,781

(22) Filed: Jun. 14, 2019

(30) Foreign Application Priority Data
Jun. 19, 2018 (JP) 2018-116215

(51) Int. Cl. H01L 21/02; H01J 37/32

(52) U.S. Cl. CPC H01L 21/02274; H01L 21/0228; H01J 37/32532; H01L 21/02186; H01J 37/32449; H01L 21/02205

(57) ABSTRACT

There is provided a method of forming a metal film. The method includes forming a first metal film on a substrate accommodated in a processing container using a plasma CVD method by supplying a first gas including a metal precursor gas and a plasma excitation gas, and a second gas including a reducing gas and a plasma excitation gas into the processing container and after the forming the first metal film, forming a second metal film on the first metal film using a plasma CVD method by supplying a third gas including the metal precursor gas and the plasma excitation gas, and a fourth gas including the reducing gas and the plasma excitation gas into the processing container.

### CROSS-REFERENCE TO RELATED APPLICATION

This application is based upon and claims the benefit of priority from Japanese Patent Application No. 2018-116215, filed on Jun. 19, 2018, the entire contents of which are incorporated herein by reference.

### TECHNICAL FIELD

The present disclosure relates to a method of forming a metal film, and a film forming apparatus.

### BACKGROUND

A technique for forming a titanium (Ti) film utilizing a plasma CVD method using a TiCl₄ gas as a precursor gas, a H₂ gas as a reducing gas, and an Ar gas as a plasma excitation gas is known.

### SUMMARY

Some embodiments of the present disclosure provide a technique capable of controlling the in-plane distribution of film thickness of a metal film formed on a substrate.

According to one embodiment of the present disclosure, there is provided a method of forming a metal film, including: forming a first metal film on a substrate accommodated in a processing container using a plasma CVD method by supplying a first gas including a metal precursor gas and a plasma excitation gas, and a second gas including a reducing gas and a plasma excitation gas into the processing container; and after the forming the first metal film, forming a second metal film on the first metal film using a plasma CVD method by supplying a third gas including the metal precursor gas and the plasma excitation gas, and a fourth gas including the reducing gas and the plasma excitation gas into the processing container.

According to another embodiment of the present disclosure, there is provided a film forming apparatus including: a processing container in which a substrate is accommodated; a gas supply part configured to supply a gas to the processing container; and a controller configured to control operations of the gas supply part, wherein the controller controls the gas supply part to perform a process including: forming a first metal film on the substrate by a plasma CVD method by supplying a first gas including a metal precursor gas and a plasma excitation gas, and a second gas including a reducing gas and a plasma excitation gas into the processing container; and after the forming the first metal film, forming a second metal film on the first metal film by a plasma CVD method by supplying a third gas including the metal precursor gas and the plasma excitation gas, and a fourth gas including the reducing gas and the plasma excitation gas into the processing container.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a sectional view illustrating a configuration example of a film forming apparatus.

FIG. 2 is a flowchart illustrating an example of a method of forming a metal film.

FIG. 3 is a flowchart illustrating an example of a pre-coating process.

FIG. 4 is a view illustrating the relationship between the Ar flow rate of a TiCl₄ line and the in-plane uniformity of film thickness of a Ti film.

### DETAILED DESCRIPTION

Reference will now be made in detail to various embodiments, examples of which are illustrated in the accompanying drawings. Throughout the drawings, the same or corresponding members or parts are denoted by the same or corresponding reference numerals, and explanations thereof will not be repeated. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### (Film Forming Apparatus)

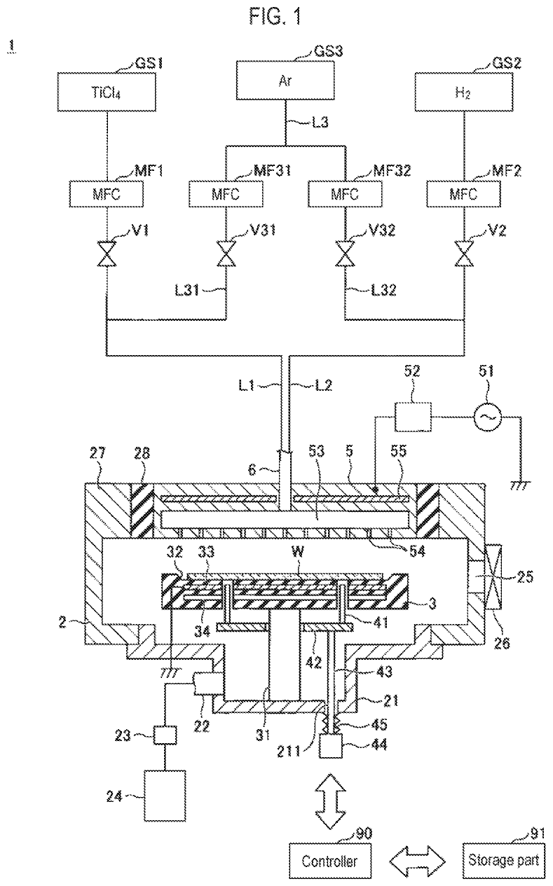

A configuration example of a film forming apparatus according to an embodiment of the present disclosure will be described. FIG. 1 is a sectional view showing a configuration example of a film forming apparatus.

Referring to FIG. 1, a film forming apparatus 1 is an apparatus that performs a process of forming a titanium (Ti) film on a semiconductor wafer (hereinafter referred to as a “wafer W”), which may be a substrate using a plasma CVD method. The film forming apparatus 1 includes a substantially cylindrical airtight processing container 2. An exhaust chamber 21 is disposed in a central portion of a bottom wall of the processing container 2.

The exhaust chamber 21 may have a substantially cylindrical shape protruding downward. An exhaust path 22 may be connected to the exhaust chamber 21 on a side surface of the exhaust chamber 21.

An exhaust part 24 is connected to the exhaust path 22 via a pressure regulating part 23. The pressure regulating part 23 includes a pressure regulating valve such as a butterfly valve. The exhaust path 22 is configured so that an interior of the processing container 2 is depressurized by the exhaust part 24. A transfer port 25 is disposed on a side surface of the processing container 2. The transfer port 25 is configured to be opened/closed by a gate valve 26. The wafer W is loaded/unloaded between the processing container 2 and a transfer chamber (not shown) via the transfer port 25.

A stage 3 which is a substrate mounting table for holding the wafer W substantially horizontally is installed in the processing container 2. The stage 3 has a substantially circular shape when viewed from the top and is supported by a support member 31. A circular recess 32 for mounting the wafer W having, for example, a diameter of 300 mm is formed on a surface of the stage 3. The stage 3 is made of a ceramic material such as aluminum nitride (AlN). Alternatively, the stage 3 may he made of a metal material such as nickel (Ni). Instead of the recess 32, a guide ring for guiding the water W may be installed on a peripheral edge portion of the surface of the stage 3.

For example, a grounded lower electrode 33 may be buried in the stage 3. A heating mechanism 34 is buried under the lower electrode 33. The heating mechanism 34 heats the wafer W mounted on the stage 3 to a set temperature (for example, a temperature of 350 to 700 degrees C.) by being fed with power from a power supply (not shown) based on a control signal from a controller 90. In the case where the entire stage 3 is made of metal, as the entire stage 3 functions as a lower electrode, the lower electrode 33 need not be buried in the stage 3. A plurality of lift pins 41 (for example, three lift pins 41) to hold and lift up/down the wafer W mounted on the stage 3 are installed in the stage 3. The lift pins 41 may be made of ceramic material such as alumina (Al₂O₃), quartz. The lower ends of the lift pins 41 are attached to a support plate 42. The support plate 42 is connected to an elevating mechanism 44 installed outside the processing container 2 via an elevating shaft 43.

The elevating mechanism 44 may be installed in a lower portion of the exhaust chamber 21. A bellows 45 is installed between an opening 211 for the elevating shaft 43, which is formed on a lower surface of the exhaust chamber 21, and the elevating mechanism 44. The support plate 42 may be shaped such that it is capable of moving up and down without interfering with the support member 31 of the stage 3. The lift pins 41 are configured to be vertically moved up and down between an upper side of the surface of the stage 3 and a lower side of the surface of the stage 3 by the elevating mechanism 44.

A gas supply part 5 is installed on a ceiling wall 27 of the processing container 2 via an insulating member 28. The gas supply part 5 forms an upper electrode and faces the lower electrode 33. A high frequency power supply 51 is connected to the gas supply part 5 via a matching device 52. The high frequency power supply 51 is configured to supply high frequency power to the upper electrode (the gas supply part 5) so as to generate a high frequency electric field between the upper electrode (gas supply part 5) and the lower electrode 33. The gas supply part 5 includes a hollow gas supply chamber 53. A plurality of holes 54 for dispersing and supplying a process gas into the processing container 2 may be equally arranged on a lower surface of the gas supply chamber 53. A heating mechanism 55 may be buried in the gas supply part 5 above the gas supply chamber 53. The heating mechanism 55 is heated to a set temperature by being supplied with power from a power supply (not shown) based on a control signal from the controller 90.

A gas supply path 6 is installed in the gas supply chamber 53. The gas supply path 6 communicates to the gas supply chamber 53. A gas source GS1 and a gas source GS2 are connected to the upstream side of the gas supply path 6 via a gas line L1 and a gas line L2, respectively. A gas source GS3 is connected to the gas line L1 via a gas line L31 and a gas line L3. The gas source GS3 is connected to the gas line L2 via a gas line L32 and the gas line L3. In the example of FIG. 1, the gas source GS1 is a gas source of TiCl₄, the gas source GS2 is a gas source of H₂, and the gas source GS3 is a gas source of Ar. However, the gas source GS1 may be a gas source of other metal raw materials (for example, WCl₆, WCl₅, WF₆, TaCl₅ or AlCl₃ which is a metal raw material containing a halogen element, or an organic raw material containing Co, Mo, Ni, Ti, W or Al), the gas source GS2 may be a gas source of other reducing gas (for example, NH₃, hydrazine or monomethylhydrazine), and the gas source GS3 may be a gas source of other inert gas (for example, N₂, He, Ne, Kr or Xe). The gas line L1 and the gas line L2 are interconnected between a valve V1 in the gas line L1 and the gas supply path 6, and between a valve V2 in the gas line L2 and the gas supply path 6.

The gas source GS1 is connected to the gas supply path 6 via the gas line L1. A flow rate controller MF1 and the valve V1 are installed in the gas line L1 in this order from the side of the gas source GS1. As a result, TiCl₄ supplied from the gas source GS1 is supplied to the gas supply path 6 with its flow rate controlled by the flow rate controller MF1.

The gas source GS2 is connected to the gas supply path 6 via the gas line L2. A flow rate controller MF2 and the valve V2 are installed in the gas line L2 in this order from the side of the gas source GS2. As a result, H₂ supplied from the gas source GS2 is supplied to the gas supply path 6 with its flow rate controlled by the flow rate controller MF2.

The gas source GS3 is connected between the valve V1 in the gas line L1 and the gas supply path 6 via the gas line L3 and the gas line L31. A flow rate controller MF31 and a valve V31 are installed in the gas line L31 in this order from the side of the gas source GS3. As a result, Ar supplied from the gas source GS3 is supplied to the gas line L1 with its flow rate controlled by the flow rate controller MF31, mixed with TiCl₄ flowing through the gas line L1 and supplied to the gas supply path 6. The gas source GS3 is also connected between the valve V2 in the gas line L2 and the gas supply path 6 via the gas line L3 and the gas line L32. A flow rate controller MF32 and a valve V32 are installed in the gas line L32 in this order from the side of the gas source GS3. As a result, Ar supplied from the gas source GS3 is supplied to the gas line L2 with its flow rate controlled by the flow rate controller MF32, mixed with H₂ flowing through the gas line L2, and supplied to the gas supply path 6. With this configuration, Ar supplied from the gas source GS3 can be supplied to the gas line L1 and the gas line L2, respectively, with its flow rate controlled by the flow rate controller MF31 and the flow rate controller MF32.

The film forming apparatus 1 includes the controller 90 and a storage part 91. The controller 90 may include a CPU, a RAM, a ROM and the like (not shown) and integrally controls the film forming apparatus 1 by causing the CPU to execute a computer program stored in the ROM or the storage part 91. Specifically, the controller 90 causes the CPU to execute a control program stored in the storage part 91 to control the operation of respective components of the film forming apparatus 1, thereby performing a method of forming a metal film as will be described below.

### (Method of Forming Metal Film)

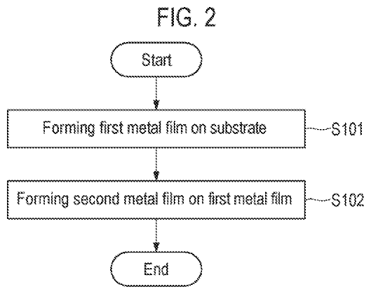

A method for forming a metal film according to an embodiment of the present disclosure will be described below. FIG. 2 is a flowchart showing an example of a method of forming a metal film.

First, step S101 of forming a first metal film on a substrate is performed. In step S101, a first gas including a metal precursor gas and a plasma excitation gas and a second gas including a reducing gas and a plasma excitation gas are supplied into the processing container in which the substrate is accommodated, to thereby form the first metal film on the substrate by a plasma CVD Method. The metal precursor gas may be a Ti precursor gas such as TiCl₄, a W precursor gas such as WCl₆, WCl₅ or WF₆, a Ta precursor gas such as TaCl₅, an Al precursor gas such as AlCl₃, or an organic gas containing Co, Mo, Ni, Ti, W or Al. The reducing gas may be a hydrogen-containing gas such as H₂, NH₃, hydrazine or monomethyl hydrazine or the like. The plasma excitation gas may be an inert gas such as Ar, N₂, He, Ne, Kr, Xe or the like.

Subsequently, step S102 of forming a second metal film on the first metal film is performed. In step S102, a third gas including a metal precursor gas and a plasma excitation gas and a fourth gas including a reducing gas and a plasma excitation gas are supplied into the processing container, to thereby form the second metal film on the first metal film. The metal precursor gas, the reducing gas and the plasma excitation gas may be the same gases as in Step S101.

According to the metal film forming method according to the embodiment of the present disclosure, in step S101 of forming the first metal film and step S102 of forming the second metal film, a metal precursor gas and a plasma excitation gas are mixed in advance and a reducing gas and a plasma excitation gas are mixed in advance. Subsequently, a first gas (third gas) which is a mixture s of the metal precursor gas and the plasma excitation gas and a second gas (fourth gas) which is a mixture of the reducing gas and the plasma excitation gas are mixed and supplied into the processing container. As a result, by controlling the flow rate of the plasma excitation gas in step S101 of forming the first metal film and step S102 of forming the second metal film, it is possible to easily determine the in-plane distribution of film thickness of a metal film formed on the substrate.

It is preferable that the flow rate of the plasma excitation gas of the first gas and the flow rate of the plasma excitation gas of the second gas are substantially equal to each other. As a result, since the gas flow rates of the gas line L1 and the gas line L2 can be balanced, when the gas line L1 and the gas line L2 join in the gas supply path 6, a gas backflow or the like is unlikely to occur and the respective gases can be easily mixed, thereby improving the in-plane uniformity of the metal films formed on the substrate.

It is also preferable that the flow rate of the plasma excitation gas of the third gas is equal to or higher than the flow rate of the plasma excitation gas of the fourth gas. As a result, since the metal precursor gas included in the third gas can be easily diffused onto the surface of the substrate in the processing chamber, it is possible to improve the in-plane uniformity of the metal films formed on the substrate.

It is also preferable that the flow rate ratio of the plasma excitation gas of the first gas to the plasma excitation gas of the second gas is equal to or lower than the flow rate ratio of the plasma excitation gas of the third gas to the plasma excitation gas of the fourth gas. As a result, if the flow rate of the metal precursor gas of the third gas is higher than the flow rate of the metal precursor gas of the first gas, and the flow rate of the reducing gas of the fourth gas is lower than the flow rate of the reducing gas of the second gas, that is, if the flow rate of the metal precursor gas is increased relative to the reducing gas when mixing the third gas and the fourth gas, or if the flow rate of the metal precursor gas itself is increased, since the diffusion of the metal precursor gas is further progressed by the plasma excitation gas, it is possible to improve the in-plane uniformity of the metal films formed on the substrate.

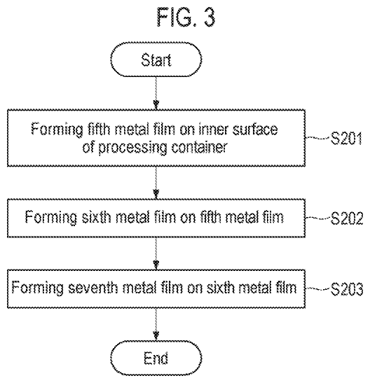

Next, a pre-coating process which is preferably performed before step S101 of forming the first metal film in the above-described metal film forming method will be described. FIG. 3 is a flowchart showing an example of a pre-coating process.

The pre-coating process is a process performed before step S101 which is forming the first metal film. Specifically, the pre-coating process is a process of pre-coating an inner surface of the processing container with a metal film by forming the metal film on the inner surface of the processing container by supplying a gas containing a metal precursor gas and a reducing gas into the processing chamber. The pre-coating process is carried out in a state where the substrate is not mounted on the stage.

First, step S201 of forming a fifth metal film on the inner surface of the processing container is performed. In step S201, a fifth metal film is formed on the inner surface of the processing container by supplying a fifth gas containing a metal precursor gas and a reducing gas into the processing chamber. In addition, in step S201, a plasma excitation gas may be supplied while being mixed with each of the metal precursor gas and the reducing gas. Further, in step S201, plasma of the fifth gas may be generated. It is preferable that the flow rate ratio of the reducing gas to the metal precursor gas of the fifth gas is higher than the flow rate ratio of a reducing gas to a metal precursor gas of a sixth gas to be described later, and is higher than the flow rate ratio of a reducing gas to a metal precursor gas of a seventh gas to be described later. Further, it is preferable that the metal precursor gas of the fifth gas is lower than the flow rate of the metal precursor gas of the sixth gas, and is lower than the flow rate of the metal precursor gas of a seventh gas. As a result, since the fifth gas has a high reducing power, the adhesion of the fifth metal film to the inner surface of the processing container is enhanced. In addition, since the fifth metal film is interposed between a sixth metal film, which will be described later, and the inner surface of the processing container, a metal-containing multilayer film has high adhesion to the inner surface of the processing container. As a result, even when the film forming process is performed on the substrate after the pre-coating process, generation of particles from e metal-containing multilayer film is suppressed, thereby reducing the number of particles on the substrate. The metal precursor gas and the reducing gas may be the same as those in step S101.

Subsequently, step S202 of forming a sixth metal film on the fifth metal film is performed. In step S202, a sixth metal film is formed on the fifth metal film by supplying a sixth gas including a metal precursor gas and a reducing gas into the processing container. In addition, in step S202, a plasma excitation gas may be supplied while being mixed with each of the metal precursor gas and the reducing gas. Further, in step S202, plasma of the sixth gas may be generated. The metal precursor gas and the reducing gas may be the same as those in Step S101.

Subsequently, step S203 of forming a seventh metal film on the sixth metal film is performed, In step S203, a seventh metal film is formed on the sixth metal film by supplying a seventh gas including a metal precursor gas and a reducing gas into the processing chamber. In addition, in step S203, a plasma excitation gas may be supplied while being mixed with each of the metal precursor gas and the reducing gas. Further, in step S203, plasma of the seventh gas may be generated. It is preferable that the flow rate ratio of the reducing gas to the metal precursor gas of the seventh gas is lower than the flow rate ratio of the reducing gas to the metal precursor gas of the sixth gas. Further, it is preferable that the metal precursor gas of the seventh gas is equal to or higher than the flow rate of the metal precursor gas of the sixth gas. As a result, since the metal precursor is decomposed while the metal precursor gas is being sufficiently diffused in the processing container, the coatability of the metal-containing multilayer film on the inner surface of the processing container is improved.

Hereinafter, a case where a Ti film which is an example of a metal film is formed after carrying out the pre-coating of the inner surface of the processing container using the film forming apparatus 1 described with reference to FIG. 1 will be described in detail by way of an example. However, a pre-coating process may not be carried out. A metal film forming method to be described below is performed by the controller 90 controlling the respective components of the film forming apparatus 1.

First, a pre-coating process is performed. To begin with, in a state in which the transfer port 25 is closed by the gate valve 26 and a wafer W as an example of the substrate is not mounted on the stage 3 in the processing container 2, the internal pressure of the processing container 2 is reduced to a predetermined pressure by the exhaust part 24 and the stage 3 is heated to a predetermined temperature by the heating mechanism 34.

Subsequently, in order to form the fifth metal film, by opening the valves V1 and V31, TiCl₄ as an example of the metal precursor gas supplied from the gas source GS1 and Ar as an example of the plasma excitation gas supplied from the gas source GS3 are mixed in the gas line L1 and introduced into the gas supply path 6. In addition, by opening the valves V2 and V32, H₂ as an example of the reducing gas supplied from the gas source GS2 and Ar as an example of the plasma excitation gas supplied from the gas source GS3 are mixed in the gas line L2 and introduced into the gas supply path 6. The gases introduced into the gas supply path 6 are dispersed and supplied into the processing container 2 from the plurality of holes 54 through the gas supply chamber 53. Further, by supplying high frequency power from the high frequency power supply 51 to the upper electrode (the gas supply part 5), a high frequency electric field is generated between the upper electrode (the gas supply part 5) and the lower electrode 33 to plasmarize the gases. As a result, a Ti film which is an example of the fifth metal film is formed on the inner surface of the processing container 2 including the surface of the stage 3.

In this way, in one embodiment, TiCl₄ and Ar are previously mixed in the gas line L1 and H₂ and Ar are previously mixed in the gas line L2, and then both mixed gases are mixed in the gas supply path 6 and supplied into the processing container 2. However, after previously mixing TiCl₄ and Ar in the gas line L1 and mixing H₂ and Ar in the gas line L2, both mixed gases may be mixed in the gas supply chamber 53 and supplied into the processing container Alternatively, after mixing TiCl₄ and Ar in the gas line L1 and mixing H₂ and Ar in the gas line L2, both gases may be supplied into the processing container 2 without being mixed. Further, the gases may not be plasmarized. Further, the flow rate controllers MF1 and MF31 can be controlled to adjust the flow rate ratio between TiCl₄ and Ar. Further, the flow rate controllers MF2 and MF32 can be controlled to adjust the flow rate ratio between H₂ and Ar. In one embodiment, the flow rate ratio of H₂ to TiCl₄ of the fifth gas is higher than the flow rate ratio of H₂ to TiCl₄ of the sixth gas, and is higher than the flow rate ratio of H₂ to TiCl₄ of the seventh gas. Further, the flow rate of TiCl₄ of the fifth gas is lower than the flow rate of TiCl₄ of the sixth gas, and is lower than the flow rate of TiCl₄ of the seventh gas.

Subsequently, in order to form the sixth metal film on the surface of the fifth metal film, in a state where the valves V1 and V31 are opened, TiCl₄ supplied from the gas source GS1 and Ar supplied from the gas source GS3 are mixed in the gas line L1 and introduced into the gas supply path 6. Further, in a state where the valves V2 and V32 are opened, H₂ supplied from the gas source GS2 and Ar supplied from the gas source GS3 are mixed in the gas line L2 and introduced into the gas supply path 6. The gases introduced into the gas supply path 6 are dispersed and supplied into the processing container 2 from the plurality of holes 54 through the gas supply chamber 53. Further, by supplying high frequency power from the high frequency power supply 51 to the upper electrode (the gas supply part 5), a high frequency electric field is generated between the upper electrode (the gas supply part 5) and the lower electrode 33 to plasmarize the gases. As a result, a Ti film which is an example of the sixth metal film is formed on the surface of the fifth metal film.

In this way, in one embodiment, TiCl₄ and Ar are previously mixed in the gas line L1 and H₂ and Ar are previously mixed in the gas line L2, and then both mixed gases are mixed in the gas supply path 6 and supplied into the processing container 2. However, after previously mixing TiCl₄ and Ar in the gas line L1 and mixing H₂ and Ar in the gas line L2, both mixed gases may be mixed in the gas supply chamber 53 and supplied into the processing container 2. Alternatively, after mixing TiCl₄ and Ar in the gas line L1 and mixing H₂ and Ar in the gas line L2, both gases may be supplied into the processing container out being mixed. Further, the gases may not be plasmarized. Further, the flow rate controllers MF1 and MF31 can be controlled to adjust the flow rate ratio between TiCl₄ and Ar. Further, the flow rate controllers MF2 and MF32 can be controlled to adjust the flow rate ratio between H₂ and Ar.

Subsequently, in order to form the seventh metal film on the surface of the sixth metal film, in a state where the valves V1 and V31 are opened, TiCl₄ supplied from the gas source GS1 and Ar supplied from the gas source GS3 are mixed in the gas line L1 and introduced into the gas supply path 6. Further, in a state where the valves V2 and V32 are opened, H₂ supplied from the gas source GS2 and Ar supplied from the gas source GS3 are mixed in the gas line L2 and introduced into the gas supply path 6. The gases introduced into the gas supply path 6 are dispersed and supplied into the processing container 2 from the plurality of holes 54 through the gas supply chamber 53. Further, by supplying high frequency power from the high frequency power supply 51 to the upper electrode (the gas supply part 5), a high frequency electric field is generated between the upper electrode (the gas supply part 5) and the lower electrode 33 to plasmarize the gases. As a result, a Ti film which is an example of the seventh metal film is formed on the surface of the sixth metal film.

In this way, in one embodiment, TiCl₄ and Ar are previously mixed in the gas line L1 and H₂ and Ar are previously mixed in the gas line L2, and then both mixed gases are mixed in the gas supply path 6 and supplied into the processing container 2. However, after previously mixing TiCl₄ and Ar in the gas line L1 and mixing H₂ and Ar in the gas line L2, both mixed gases may be mixed in the gas supply chamber 53 and supplied into the processing container 2. Alternatively, after mixing TiCl₄ and Ar in the gas line L1 and mixing H₂ and Ar in the gas line L2, both gases may be supplied into the processing container 2 without being mixed. Further, the gases may not be plasmarized. Further, the flow rate controllers MF1 and MF31 can be controlled to adjust the flow rate ratio between TiCl₄ and Ar. Further, the flow rate controllers MF2 and MF32 can be controlled to adjust the flow rate ratio between H₂ and Ar. In one embodiment, the flow rate ratio of H₂ to TiCl₄ of the seventh gas is lower than the flow rate ratio of H₂ to TiCl₄ of the sixth gas, and the flow rate of TiCl₄ of the seventh gas is equal to or higher than the flow rate of TiCl₄ of the sixth gas.

Next, a film forming process is performed. First, the wafer W is loaded into the processing container 2. Specifically, the gate valve 26 is opened, the wafer W is loaded into the processing container 2 through the transfer port 25 by a transfer device (not shown), and the plurality of lift pins 41 are raised to hold the wafer W. Subsequently, the transfer device is retracted from the interior of the processing container 2, and the gate valve 26 is closed. Further, the plurality of lift pins 41 are lowered to mount the wafer W on the stage 3. Subsequently, the internal pressure of the processing container 2 is reduced to a predetermined pressure by the exhaust part 24, and the wafer W is heated to a predetermined temperature by the heating mechanism 34.

Subsequently, in order to form the first metal film on the surface of the wafer W, by opening the valves V1 and V31. TiCl₄ supplied from the gas source GS1 and Ar supplied from the gas source GS3 are mixed in the gas line L1 and introduced into the gas supply path 6. In addition, by opening the valves V2 and V32, H₂ supplied from the gas source GS2 and Ar supplied from the gas source GS3 are mixed in the gas line L2 and introduced into the gas supply path 6. The gases introduced into the gas supply path 6 is dispersed and supplied into the processing container 2 from the plurality of holes 54 through the gas supply chamber 53. Further, by supplying high frequency power from the high frequency power supply 51 to the upper electrode (the gas supply part 5), a high frequency electric field is generated between the upper electrode (the gas supply part 5) and the lower electrode 33 to plasmarize the gases. As a result, a Ti film which is an example of the first metal film is formed on the surface of the wafer W.

In this way, in one embodiment, TiCl₄ and Ar are previously mixed in the gas line L1 and H₂ and Ar are previously mixed in the gas line L2, and then both mixed gases are mixed in the gas supply path 6 and supplied into the processing container 2. However, after previously mixing TiCl₄ and Ar in the gas line L1 and mixing H₂ and Ar in the gas line L2, both mixed gases may be mixed in the gas supply chamber 53 and supplied into the processing container 2. Alternatively, after mixing TiCl₄ and Ar in the gas line L1 and mixing H₂ and Ar in the gas line L2, both gases may be supplied into the processing container 2 without being mixed. Further, the flow rate controllers MF1 and MF31 can be controlled to adjust the flow rate ratio between TiCl₄ and Ar. Further, the flow rate controllers MF2 and MF32 can be controlled to adjust the flow rate ratio between H₂ and Ar. In one embodiment, the flow rate of Ar supplied into the gas line L1 is substantially equal to the flow rate of Ar supplied into the gas line L2. Incidentally, the substantial equality is meant to include the equality.

Subsequently, in order to form the second metal film on the first metal film, in a state where the valves V1 and V31 are opened, TiCl₄ supplied from the gas source GS1 and Ar supplied from the gas source GS3 are mixed in the gas line L1 and introduced into the gas supply path 6. Further, in a state where the valves V2 and V32 are opened, H₂ supplied from the gas source GS2 and Ar supplied from the gas source GS3 are mixed in the gas line L2 and introduced into the gas supply path 6. The gases introduced into the gas supply path 6 are dispersed and supplied into the processing container 2 from the plurality of holes 54 through the gas supply chamber 53. Further, by supplying high frequency power from the high frequency power supply 51 to the upper electrode (the gas supply part 5), a high frequency electric field is generated between the upper electrode (the gas supply part 5) and the lower electrode 33 to plasmarize the gases. As a result, a Ti film which is an example of the second metal film is formed on the Ti film which is an example of the first metal film.

In this way, in one embodiment, TiCl₄ and Ar are previously mixed in the gas line L1 and H₂ and Ar are previously mixed in the gas line L2, and then both mixed gases are mixed in the gas supply path 6 and supplied into the processing container 2. However, after previously mixing TiCl₄ and Ar in the gas line L1 and mixing H₂ and Ar in the gas line L2, both mixed gases may be mixed in the gas supply chamber 53 and supplied into the processing container 2. Alternatively, after mixing TiCl₄ and Ar in the gas line L1 and mixing H₂ and Ar in the gas line L2, both gases may be supplied into the processing container 2 without being mixed. Further, the flow rate controllers MF1 and MF31 can be controlled to adjust the flow rate ratio between TiCl₄ and Ar. Further, the flow rate controllers MF2 and MF32 can be controlled to adjust the flow rate ratio between H₂ and Ar. In one embodiment, the flow rate of Ar supplied into the gas line L1 is equal to or higher than the flow rate of Ar supplied into the gas line L2.

Subsequently, by closing the valves V1 and V2 in a state where the valves V31 and V32 are opened. Ar is supplied into the processing container 2 to purge TiCl₄ and H₂ remaining in the processing container 2. When the purging in the processing container 2 is completed, the valves V31 and V32 are closed, and the wafer W is unloaded from the interior of the processing container 2 according to a procedure reverse to the procedure for loading the wafer W.

According to the present disclosure, it is possible to form a Ti film having excellent in-plane distribution on the surface of the wafer W.

### EXAMPLES

Examples conducted to check the effects of the metal film forming method according to one embodiment will be described. In the examples, after performing the pre-coating process using the film forming apparatus 1, a Ti film was formed on the surface of the wafer W with the flow rate of Ar supplied into the gas line Li (TiCl₄ line) in step S101 set to 0, 100, 1,000, 1,900 and 2,000 sccm. Further, the flow rate of Ar supplied into the gas line L2 (H₂ line) was set so that the total flow rate of Ar supplied into the processing container 2 was 2,000 sccm. Further, the in-plane uniformity of film thickness of the Ti film formed on the surface of the wafer W was evaluated. The process conditions of the pre-coating process and the film forming process are as follows.

### <Step S201>

TiCl₄: 0.2 to 10 sccm
H₂: 500 to 10,000 sccm
Ar (TiCl₄ line)/Ar (H₂ line 5,000/10 to 5,000 sccm
High frequency power: 100 to 3,000 W at 450 kHz
Internal pressure of processing container: 50 to 800 Pa
Wafer temperature: 320 to 700 degrees C.

### <Step S202>

TiCl₄: 1 to 100 sccm
H₂: 500 to 10,000 sccm
Ar (TiCl₄ line)/Ar (H₂ line): 10 to 5,000/10 to 5,000 sccm
High frequency power: 100 to 3,000 W at 450 kHz
Internal pressure of processing container: 50 to 800 Pa
Wafer temperature: 320 to 700 degrees C.

### <Step S203>

TiCl₄: 5 to 100 sccm
H₂: 1 to 500 sccm
Ar (TiCl₄ line)/Ar (H₂ line): 50 to 5,000/50 to 5,000 sccm
High frequency power: 100 to 3,000 W at 450 kHz
Internal pressure of processing chamber: 50 to 800 Pa
Wafer temperature: 320 to 700 degrees C.

### <Step S101>

TiCl₄: 0.2 to 10 sccm
H₂: 500 to 10,000 sccm
Ar (TiCl₄ line)/Ar (H₂ line): 0/2,000, 100/1,900, 1,000/1,000, 1,900/100, 2,000/0 sccm
High frequency power: 100 to 3,000 W at 450 kHz
Internal pressure of processing container: 50 to 800 Pa
Wafer temperature: 320 to 700 degrees C.

### <Step S102>

TiCl₄: 5 to 100 sccm
H₂: 1 to 500 sccm
Ar (TiCl₄ line)/Ar (H₂ line): 1,100/100 sccm
High frequency power: 100 to 3,000 W at 450 kHz
Internal pressure of processing chamber: 50 to 800 Pa
Wafer temperature: 320 to 700 degrees C.

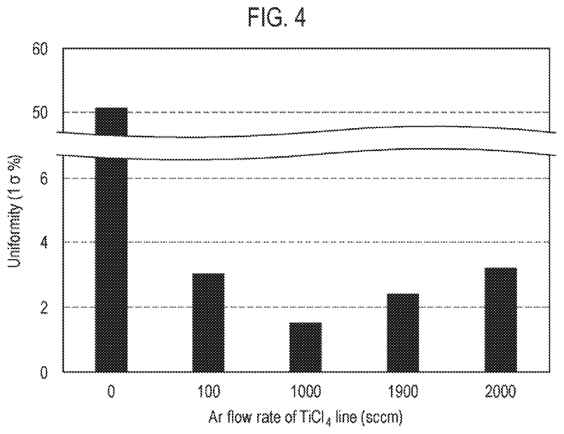

FIG. 4 is a view showing the relationship between the Ar flow rate of the TiCl₄ line and the in-plane uniformity of film thickness of the Ti film. FIG. 4 shows the in-plane uniformity (1σ%) of film thickness of the Ti film when the Ar flow rate of the TiCl₄ line is 0 sccm, 100 sccm, 1,000 sccm, 1,900 sccm and 2,000 sccm in order from left.

Referring to FIG. 4, in step S101, when the Ar flow rate of the TiCl₄ line is 0 sccm, that is, when no Ar is supplied from the TiCl₄line, the in-plane uniformity of film thickness of the Ti film is 50% (1σ%) or more. In contrast, when the Ar flow rate of the TiCl₄ line is 100, 1,000, 1,900 and 2,000 sccm, that is, when Ar is supplied from the TiCl₄ line, the in-plane uniformity of film thickness of the Ti film is 4% (1σ%) or less. From these facts, it is considered that the in-plane uniformity of film thickness of the Ti film is improved by supplying Ar from the TiCl₄ line in step S101.

Further, as can be seen from FIG. 4, in step S101, when the Ar flow rate of the TiCl₄ line is 1,000 sccm, the in-plane uniformity of film thickness of the Ti film is particularly improved. That is, when the flow rate of Ar supplied from the TiCl₄ line is equal to the flow rate of Ar supplied from the H₂ line, it can be seen that the in-plane uniformity of film thickness of the Ti film is particularly improved.

According to the present disclosure in some embodiments, it is possible to control the in-plane distribution of film thickness of a metal film formed on a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of forming a metal film, comprising:
forming a first metal film on a substrate accommodated in a processing container using a plasma CVD method by supplying a first gas including a metal precursor gas and a plasma excitation gas, and a second gas including a reducing gas and the plasma excitation gas into the processing container; and
after the forming the first metal film, forming a second metal film on the first metal film using a plasma CVD method by supplying a third gas including the metal precursor gas and the plasma excitation gas, and a fourth gas including the reducing gas and the plasma excitation gas into the processing container.

2. The method of claim 1, wherein a flow rate of the plasma excitation gas of the first gas and a flow rate of the plasma excitation gas of the second gas are substantially equal to each other.

3. The method of claim 1, wherein a flow rate of the plasma excitation gas of the third gas is equal to or higher than a flow rate of the plasma excitation gas of the fourth gas.

4. The method of claim 1, wherein a flow rate ratio of the plasma excitation gas of the first gas to the plasma excitation gas of the second gas is equal to or lower than a flow rate ratio of the plasma excitation gas of the third gas to the plasma excitation gas of the fourth gas.

5. The method of claim 1, further comprising:
forming, before the forming the first metal film, a metal film on an inner surface of the processing container by supplying a gas including the metal precursor gas and the reducing gas into the processing container.

6. The method of claim 5, wherein the forming the metal n on the inner surface of the processing container includes:
forming a fifth metal film on the inner surface of the processing container by supplying a fifth gas including the metal precursor gas and the reducing gas into the processing container;
forming a sixth metal film on the fifth metal film by supplying a sixth gas including the metal precursor gas and the reducing gas into the processing container; and
forming a seventh metal film on the sixth metal film by supplying a seventh gas including the metal precursor gas and the reducing gas into the processing container,
wherein a flow rate ratio of the reducing gas to the metal precursor gas of the fifth gas is higher than a flow rate ratio of the reducing gas to the metal precursor gas of the sixth gas, and is higher a flow rate ratio of the reducing gas to the metal precursor gas of the seventh gas, and
wherein a flow rate of the metal precursor gas of the fifth gas is lower than a flow rate of the metal precursor gas of the sixth gas, and is lower than a flow rate of the metal precursor gas of the seventh gas.

7. The method of claim 5, wherein the forming the metal film on the inner surface of the processing container is performed in a state where no substrate is present in the processing container.

8. The method of claim 1, wherein the metal precursor gas is a Ti precursor gas,
wherein the reducing gas is a hydrogen-containing gas, and
wherein the plasma excitation gas is an inert gas.

9. The method of claim 8, wherein the Ti precursor gas is TiCl₄,
wherein the hydrogen-containing gas is H₂, and
wherein the plasma excitation gas is Ar.

10. A film forming apparatus comprising:
a processing container in which a substrate is accommodated;
a gas supply part configured to supply a gas to the processing container; and
a controller configured to control operations of the gas supply part,
wherein the controller controls the gas supply part to perform a process including:
forming a first metal film on the substrate by a plasma CVD method by supplying a first gas including a metal precursor gas and a plasma excitation gas, and a second gas including a reducing gas and the plasma excitation gas into the processing container; and
after the forming the first metal film, forming a second metal film on the first metal film by a plasma CVD method by supplying a third gas including the metal precursor gas and the plasma excitation gas, and a fourth gas including the reducing gas and the plasma excitation gas into the processing container.
